(19) United States
(12) Patent Application Publication
(10) Pub. No.: US 2024/0234584 A9
(43) Pub. Date: Jul. 11, 2024

(54) SYNAPSE DEVICE, MANUFACTURING METHOD THEREOF, AND NEUROMORPHIC DEVICE INCLUDING SYNAPSE DEVICE

(71) Applicants: SK hynix Inc., Icheon (KR); Korea Advanced Institute of Science and Technology, Daejeon (KR)

(72) Inventors: Yang Kyu CHOI, Daejeon (KR); Ji Man YU, Daejeon (KR); Seong-Yeon KIM, Daejeon (KR)

(21) Appl. No.: 18/364,240

(22) Filed: Aug. 2, 2023

(30) Foreign Application Priority Data
Oct. 20, 2022 (KR) 10-2022-0135613

(51) Int. Cl. H01L 29/792; G11C 16/04; H01L 21/28; H01L 29/423; H01L 29/51; H01L 29/66

(52) U.S. Cl. CPC H01L 29/792; G11C 16/0466; H01L 29/40117; H01L 29/42348; H01L 29/513; H01L 29/518; H01L 29/66833

(57) ABSTRACT

A synapse device, a manufacturing method thereof, and a neuromorphic device including the synapse device are disclosed. The synapse device may include a channel member, a tunnel insulating layer disposed on the channel member, a charge trap layer disposed on the tunnel insulating layer, a blocking insulating layer disposed on the charge trap layer, a gate electrode disposed on the blocking insulating layer, a first terminal and a second terminal respectively connected to first and second regions of the channel member, and first and second conductors respectively bonded to the first and second terminals The charge trap layer may have a multilayer structure including a first trap layer disposed adjacent to the channel member and a second trap layer disposed adjacent to the gate electrode. The first trap layer may have a trap of a shallower level than that of the second trap layer.

### CROSS-REFERENCE TO RELATED APPLICATION

The present application claims, under 35 U.S.C. § 119(a), the benefit of Korean application No. 10-2022-0135613, filed on Oct. 20, 2022 which is herein incorporated by reference in its entirety.

### BACKGROUND

### 1. Field

Embodiments of the present disclosure relates to an electronic device, a manufacturing method thereof, and an apparatus including the electronic device, and more particularly, to a synapse device, a manufacturing method thereof, and a neuromorphic device including the synapse device.

### 2. Description of the Related Art

As the scaling reduction of transistors reaches its limit, a neuromorphic computing system is receiving a lot of attention as a new concept which may overcome the limitations of the existing von Neumann computer system. Neuromorphic computing is a system to implement artificial intelligence operations by imitating the human brain in a hardware manner. Based on the fact that the human brain performs very complex functions but consumes only about 20 W of energy, neuromorphic computing may imitate the structure of the human brain itself and may perform artificial intelligence operations of association, reasoning, and recognition that are superior to the existing von Neumann method computing with ultra-low power.

The neuromorphic system which enables such neuromorphic computing is composed of numerous neurons (neuron devices) and synapses (synaptic devices) like the human brain, and includes additional circuits for signal processing and transmission. The synapse remembers the connection strength (weight) according to the correlation of the spikes expressed by the neurons, and adjusts the connection weight through the process of strengthening/potentiation and suppression/depression as needed. As synaptic devices, resistive random access memory (RRAM) and memristor-based devices have been extensively studied, and recently, metal-oxide-semiconductor field-effect transistor (MOSFET)-based synaptic devices have also been studied.

Recently, as the amount of information to be learned and inferred during computation of a neural network for artificial intelligence increases, there is a problem that the amount of information movement between a processor and a memory greatly increases. Accordingly, nonvolatile computing-in-memory, which adjusts the synaptic weight of a neural network by modulating the conductance of a memory device in a nonvolatile memory, has received great attention and has been actively studied. In this regard, a charge trap memory is widely used in the actual industry and has excellent advantages in terms of mass production. However, when updating the weights, as the conductance modulation does not occur linearly, learning and inference accuracy of the data is reduced, and the speed of updating the weights is getting slower. Thus, the charge trap memory reveals its limitations.

### SUMMARY

A technological object to be achieved by embodiments of the present disclosure is to provide a synapse device capable of securing or improving linearity when adjusting synaptic weights and, in addition, increasing the speed of an operation related to updating weights.

In addition, the technological object to be achieved by the present invention is to provide a method for manufacturing the synapse device.

In addition, a technological object to be achieved by embodiments of the present disclosure is to provide a neuromorphic device (neuromorphic system) including the synapse device.

The object to be solved by embodiments of the present disclosure is not limited to the objects mentioned above, and other objects not mentioned will be understood by those skilled in the art from the description below.

According to one embodiment of the present disclosure, there is provided a synapse device comprising: a channel member; a tunnel insulating layer disposed on the channel member; a charge trap layer disposed on the tunnel insulating layer; a blocking insulating layer disposed on the charge trap layer; a gate electrode disposed on the blocking insulating layer; a first terminal and a second terminal respectively connected to first and second regions of the channel member; and first and second conductors respectively bonded to the first and second terminals, wherein the charge trap layer has a multilayer structure including a first trap layer disposed adjacent to the channel member and a second trap layer disposed adjacent to the gate electrode, and wherein the first trap layer has a trap of a shallower level than that of the second trap layer.

The first trap layer may be a first silicon nitride layer, and the second trap layer may be a second silicon nitride layer different from the first silicon nitride layer.

The first silicon nitride layer may be a Si-rich silicon nitride layer, and the second silicon nitride layer may be a silicon nitride layer having a higher nitrogen (N) content than the first silicon nitride layer.

The second silicon nitride layer may include silicon nitride having a stoichiometric composition, or N-rich silicon nitride, or both.

The first trap layer may have a smaller energy bandgap than that of the second trap layer.

The first terminal may be a source and the second terminal may be a drain, and source and the first conductor may form a Schottky junction, and the drain and the second conductor may form a Schottky junction.

Each of the source and the drain may have a doping concentration of about 1×10¹⁶ to 2×10¹⁸ atoms/cm³.

According to another embodiment of the present disclosure, a neuromorphic device including the synapse device described above is provided.

The neuromorphic device may further include a CMOS peripheral circuit connected to the synapse device.

According to another embodiment of the present disclosure, there is provided a method for manufacturing a synapse device comprising forming a stacked structure by sequentially stacking a tunnel insulating layer, a charge trap layer, a blocking insulating layer, and a gate electrode on a channel member; forming a first terminal and a second terminal respectively connected to first and second regions of the channel member; and forming first and second conductors respectively bonded to the first and second terminals, wherein the charge trap layer is formed to have a multilayer structure including a first trap layer disposed adjacent to the channel member and a second trap layer disposed adjacent to the gate electrode, and wherein the first trap layer has a trap of a shallower level than that of the second trap layer.

The first trap layer may be a first silicon nitride layer, and the second trap layer may be a second silicon nitride layer different from the first silicon nitride layer.

The first silicon nitride layer may be a silicon (Si)-rich silicon nitride layer, and the second silicon nitride layer may be a silicon nitride layer having a higher nitrogen (N) content than the first silicon nitride layer.

The second silicon nitride layer may include at least one of silicon nitride having a stoichiometric composition, or N-rich silicon nitride, or both.

The first trap layer may have a smaller energy bandgap than that of the second trap layer.

The first terminal may be a source and the second terminal may be a drain, and the source and the first conductor may form a Schottky junction, and the drain and the second conductor may form a Schottky junction.

Each of the source and the drain may have a doping concentration of about 1×10¹⁶ to 2×10¹⁸ atoms/cm³.

According to the embodiments of the present disclosure, it is possible to implement a synapse device capable of increasing the speed of an operation related to synaptic weight update. In addition, according to the embodiments of the present disclosure, it is possible to implement a synapse device capable of securing or improving linearity when adjusting synaptic weights. In addition, there is an advantage that the synapse device according to the embodiments has an excellent process compatibility with CMOS (complementary metal oxide semiconductor) technology.

Therefore, the synapse device according to the embodiments may be used as an artificial synapse which may replace a biological synapse, and may be usefully used for a neuromorphic device (neuromorphic system) and a neural network.

However, the effects of the present disclosure are not limited to the above effects, and may be variously extended without departing from the technological spirit and scope of the present disclosure.

### BRIEF DESCRIPTION OF THE DRAWINGS

FIG. 1 is a cross-sectional view showing a synapse device according to an embodiment of the present disclosure.

FIG. 2 is a graph showing the results obtained by performing a composition analysis on a charge trap layer that may be applied to the synapse device according to an embodiment of the present disclosure.

FIG. 3 is a diagram showing an energy band diagram of a synapse device according to an embodiment of the present disclosure.

FIG. 4 is a diagram showing energy band diagram of a channel region, a source/drain, and a conductor of a synapse device according to an embodiment of the present disclosure.

FIG. 5 is a graph showing a change in the drain current I_{D} according to a change in the gate voltage (V_{G}) of a synapse device according to an embodiment of the present disclosure.

FIG. 6 is a graph showing the result obtained by evaluating the conductance increase characteristic according to the number of voltage pulses applied to a synapse device according to an embodiment of the present disclosure.

FIG. 7 is a graph showing results of evaluation of potentiation and depression characteristics of a synapse device according to an embodiment of the present invention and a synapse device according to a comparative example.

FIG. 8 is a cross-sectional view showing a circuit configuration including a synapse device according to an embodiment of the present disclosure.

FIG. 9 is a circuit diagram showing a synaptic array device to which a synapse device according to an embodiment of the present disclosure is applied as a unit device.

FIGS. 10A, 10B, 10C, and 10D are cross-sectional views showing a manufacturing method of a synapse device according to an embodiment of the present disclosure.

### DETAILED DESCRIPTION

Hereinafter, the embodiments of the present disclosure will be described in detail with reference to the accompanying drawings.

The embodiments of the present disclosure to be described below are provided to more clearly explain various embodiments of the present disclosure to those skilled in the art, and the scope of embodiments of the present disclosure is not limited by the following embodiments, and the embodiments may be modified in many different forms.

The terms used in this specification are used to describe specific embodiments and are not intended to limit embodiments of the present disclosure. The terms indicating a singular form used herein may include plural forms unless the context clearly indicates otherwise. Also, as used herein, the terms, “comprise” and/or “comprising” specify the presence of the stated shape, step, number, operation, member, element, and/or group thereof and do not exclude the presence or addition of one or more other shapes, steps, numbers, operations, elements, elements and/or groups thereof. In addition, the term, “connection” used in this specification indicates not only a direct connection of certain members, but also an indirect connection in which one or more other members are interposed between the connected members.

In addition, in the present specification, when a member is said to be located “on” another member, this arrangement includes not only a case in which a member is in contact with another member, but also a case where another member exists between the two members. As used herein, the term, “and/or” includes any one and all combinations of one or more of the listed items. In addition, the terms of degree such as “about” and “substantially” used in the present specification are used as a range of values or degrees, or as a meaning close thereto, taking into account inherent manufacturing and material tolerances, and exact or absolute figures provided to aid in the understanding of this application are used to prevent the infringers from unfairly exploiting the stated disclosure.

Hereinafter, embodiments of the present disclosure will be described in detail with reference to the accompanying drawings. A size or a thickness of areas or parts shown in the accompanying drawings may be slightly exaggerated for clarity of the specification and convenience of description. The same reference numbers indicate the same configuring elements throughout the detailed description.

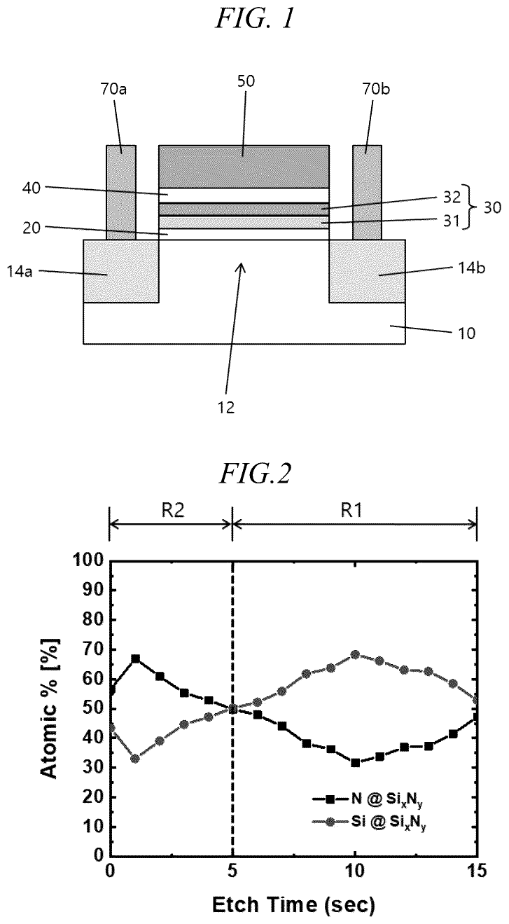

FIG. 1 is a cross-sectional view showing a synapse device according to an embodiment of the present disclosure.

Referring to FIG. 1, a synapse device according to an embodiment of the present disclosure includes a channel member 12, a tunnel insulating layer 20 disposed on the channel member 12, and a charge trap layer 30 disposed on the tunnel insulating layer 20, a blocking insulating layer 40 disposed on the charge trap layer 30, and a gate electrode 50 disposed on the blocking insulating layer 40. In addition, the synapse device may include a source 14a and a drain 14b respectively connected to first and second regions of the channel member 12, and first and second conductors 70a and 70b respectively coupled (e.g., bonded) to the source 14a and the drain 14b. The source 14a may be connected to (e.g., be contact with) the first region (e.g., a first end portion) of the channel member 12, and the drain 14b may be connected to (e.g., be contact with) the second region (e.g., a second end portion) of the channel member 12. The channel member 12 may be formed in a predetermined region of a substrate 10, and the source 14a and the drain 14b may be formed in regions of the substrate 10 on both sides of the channel member 12. The channel member 12 may be referred to as a ‘channel region’, and the source 14a and drain 14b may be referred to as a ‘source region’ and a ‘drain region’, respectively.

The substrate 10 may be, for example, a semiconductor substrate such as a silicon substrate. The silicon substrate may be a single crystal substrate. In this case, the channel member 12 may be, for example, a region (e.g., silicon region) doped with a first type of dopant (e.g., P-type dopant). Meanwhile, the source 14a and the drain 14b may be regions (silicon regions) doped with a second type of dopant (e.g., N-type dopant). However, the material of the substrate 10 is not limited to silicon and may be changed according to circumstances. For example, the substrate 10 may be any one of various substrates such as a silicon substrate, a germanium substrate, a silicon-germanium substrate, and a silicon carbide substrate.

The tunnel insulating layer 20 may be formed of an insulating material such as, for example, silicon oxide (e.g., SiO₂) However, the material of the tunnel insulating layer 20 is not limited to silicon oxide and may be varied in some cases.

The blocking insulating layer 40 may be formed of an insulating material such as, for example, silicon oxide (e.g., SiO₂) However, the material of the blocking insulating layer 40 is not limited to silicon oxide, and may be varied in some cases.

The gate electrode 50 may include, for example, silicon. In this case, the gate electrode 50 may include highly doped polycrystalline silicon. However, the material of the gate electrode 50 is not limited thereto and may be variously changed depending on the case.

The charge trap layer 30 may have a multilayer structure. The charge trap layer 30 may have a multilayer structure including a first trap layer 31 disposed adjacent to the channel member 12 and a second trap layer 32 disposed adjacent to the gate electrode 50. The multilayer structure may be, for example, a double-layer structure. The first trap layer 31 may be disposed to contact the tunnel insulating layer 20. The first trap layer 31 may be disposed between the tunnel insulating layer 20 and the second trap layer 32. The second trap layer 32 may be disposed to be in contact with the blocking insulating layer 40. The second trap layer 32 may be disposed between the first trap layer 31 and the blocking insulating layer 40.

The first trap layer 31 may have a trap of a shallower level than that of the second trap layer 32, that is, the second trap layer 32 may have a trap of a deeper level than that of the first trap layer 31. In other words, the first trap layer 31 may have a shallower trap level than the second trap layer 32, that is, the second trap layer 32 may have a deeper trap level than the first trap layer 31. Also, the first trap layer 31 may have a smaller energy bandgap than that of the second trap layer 32.

When the charge trap layer 30 includes the first trap layer 31 and the second trap layer 32 as described above, as the charges (electrons) trapped in shallow traps of the first trap layer 31 may escape to the channel member 12 at a relatively high speed when a potentiation voltage (e.g., erase voltage) is applied, the synaptic operation speed may be improved. Specifically, since charges trapped in the first trap layer 31 may be discharged to the channel member 12 at a relatively high speed, an operation speed of a synapse device including the first and second trap layers 31 and 32 may be higher than that of a conventional synapse device having a single charge trap layer. In other words, the update speed of the weight of the synapse device may be increased. When the first trap layer 31 has a smaller energy bandgap than that of the second trap layer 32, the operation speed improvement effect may be further improved. Meanwhile, since the second trap layer 32 has a deep trap, charge retention characteristics of the charge trap layer 30 may be improved (secured) due to the second trap layer 32. During the potentiation operation by applying the potentiation voltage, the charges (electrons) trapped in the deep trap of the second trap layer 32 may move to the shallow trap of the first trap layer 31, and then, may exit to the channel member 12.

The first trap layer 31 and the second trap layer 32 may have different material configurations (compositions). The first trap layer 31 may be a first silicon nitride layer, and the second trap layer 32 may be a second silicon nitride layer different from the first silicon nitride layer. The first silicon nitride layer may be a Si-rich silicon nitride layer. When the first silicon nitride layer is referred to as SiₓN_{y}, x and y may satisfy the conditional expression x/y>¾. The content of Si (silicon) in the first silicon nitride layer may be greater than 300/7 at %, and may be less than 600/7 at %. In other words, the Si content in the first silicon nitride layer may be greater than about 43 (e.g., 42.857) at %, and less than about 86 (e.g., 85.714) at %. When the Si content in the first silicon nitride layer is greater than about 43 at %, and less than about 86 at %, the operation speed of a synapse device including the first silicon nitride layer is significantly and unexpectedly increased compared to when the Si content in the first silicon nitride layer lies outside the range.

The second silicon nitride layer may be a silicon nitride layer having a higher nitrogen (N) content than the first silicon nitride layer. For example, the second silicon nitride layer may include silicon nitride having a stoichiometric composition, or N-rich silicon nitride, or both. When the second silicon nitride layer is referred to as SiₓN_{y}, x and y may satisfy the conditional expression x/y≤¾. The content of Si in the second silicon nitride layer may be equal to or less than 300/7 at %, and may be greater than 100/7 at %. In other words, the Si content in the second silicon nitride layer may be greater than about 14 (e.g., 14.285) at % and equal to or less than about 43 (e.g., 42.857) at %. When the Si content in the second silicon nitride layer is greater than about 14 at % and less than about 43 at %, the charge retention characteristics of the charge trap layer 30 is significantly and unexpectedly improved compared to when the Si content in the second silicon nitride layer lies outside the range.

When the first trap layer 31 is composed of the first silicon nitride layer and the second trap layer 32 is composed of the second silicon nitride layer, the first trap layer 31 may have trap of a shallower level than that of the second trap layer 32, That is, the second trap layer 32 may have trap of a deeper level than that of the first trap layer 31. Also, the first trap layer 31 may have a smaller energy bandgap than that of the second trap layer 32.

Meanwhile, a thickness of the first trap layer 31 may be substantially the same as or different from a thickness of the second trap layer 32. As a non-limiting example, the thickness of the first trap layer 31 may be about 2 to 5 nm. The thickness of the second trap layer 32, as a non-limiting example, may be about 2 to 5 nm. When these thickness conditions are satisfied, it may be advantageous to secure excellent charge trap characteristics and synaptic operation speed improvement characteristics.

Also, according to an embodiment of the present invention, the source 14a and the first conductor 70a may form a Schottky junction, and the drain 14b and the second conductor 70b may form a Schottky junction. In other words, a Schottky contact may be formed between the source 14a and the first conductor 70a, and similarly, a Schottky contact may be formed between the drain 14b and the second conductor 70b.

The first and the second conductors 70a and 70b may be made of a predetermined metal or metallic material. As the material of the first and the second conductors 70a and 70b, any metal contact material of a general electronic device may be applied. Each of the source 14a and the drain 14b may have a doping level corresponding to the N− level. For example, each of the source 14a and the drain 14b may have a doping concentration of about 1×10¹⁶ to 2×10¹⁸ atoms/cm³. Under these conditions, the source 14a may form a Schottky junction with the first conductor 70a, and the drain 14b may form a Schottky junction with the second conductor 70b.

As such, when a Schottky junction is formed between the source 14a/drain 14b and the first conductor 70a/second conductor 70b, unlike a typical charge trap-based device, a current section due to a tunneling (TU) mechanism may be generated between a current section due to a thermionic emission (TE) mechanism and a current section due to a drift mechanism, and linearity of weight control (update) of the synapse device may be easily secured by using the current section due to the tunneling (TU) mechanism. For example, the weight of a synapse device according to an embodiment of the present disclosure characterized by conductance of device may substantially linearly vary with the number of pulses applied to the device in the current section due to the tunneling (TU) mechanism, thereby improving linearity of the device compared to a conventional charge trap-based memory device without having the current section due to the tunneling (TU) mechanism.

Although not shown in FIG. 1, an interlayer insulating layer may be further formed around the first and second conductors 70a and 70b. The interlayer insulating layer may be formed on the substrate 10 to cover the source 14a and the drain 14b, and first and the second contact holes may be formed in the interlayer insulating layer. The first and the second conductors 70a and 70b may be respectively formed in the first and the second contact holes. The first and the second conductors 70a and 70b may be referred to as a kind of conductive plug.

FIG. 2 is a graph showing the results obtained by performing a composition analysis on a charge trap layer that may be applied to a synapse device according to an embodiment of the present disclosure. That is, FIG. 2 shows the result obtained by composition analysis in the depth direction while etching is being performed from an upper surface of the charge trap layer.

Referring to FIG. 2, the charge trap layer that may be applied to the synapse device according to an embodiment of the present disclosure may have a multilayer structure including a first trap layer disposed adjacent to a channel member and a second trap layer disposed adjacent to a gate electrode. The first trap layer may be a first silicon nitride layer, and the second trap layer may be a second silicon nitride layer different from the first silicon nitride layer. The first silicon nitride layer may be a Si-rich silicon nitride layer, and the second silicon nitride layer may be a silicon nitride layer having a higher nitrogen (N) content than that of the first silicon nitride layer. The second silicon nitride layer may include silicon nitride having a stoichiometric composition, or N-rich silicon nitride, or both.

In FIG. 2, the R1 region represents a region in which the Si (silicon) content is higher than the N (nitrogen) content. The R2 region represents a region in which the N content is higher than the Si content. At least a portion of the material layer corresponding to the R1 region may correspond to the first trap layer. At least a portion of the material layer corresponding to the R2 region may correspond to the second trap layer. The data of FIG. 2 may contain some degree of measurement error.

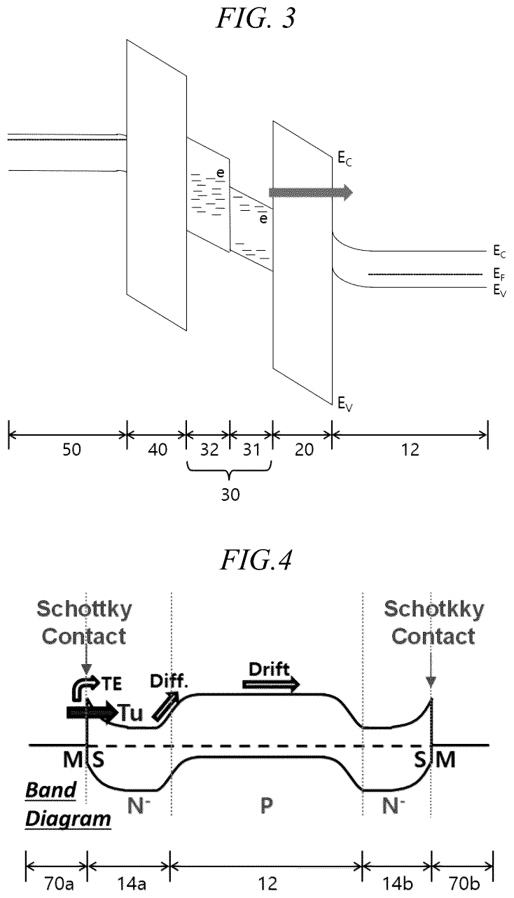

FIG. 3 is a diagram showing an energy band diagram of a synapse device according to an embodiment of the present disclosure. The reference numbers of main layers in FIG. 3 may be the same as those described in FIG. 1. In addition, in FIG. 3, E_{C} denotes a minimum conduction band level, E_{V} denotes a maximum valence band level, and E_{F} denotes a Fermi energy level.

Referring to FIG. 3, the synapse device according to an embodiment of the present disclosure may include a channel region 12, a tunnel insulating layer 20, a charge trap layer 30, a blocking insulating layer 40, and a gate electrode 50. Here, the charge trap layer 30 may include a first trap layer 31 and a second trap layer 32. For example, the channel region 12 may be a p-type Si region, the tunnel insulating layer 20 may be a SiO₂ layer, the first trap layer 31 may be a first silicon nitride layer, and the second trap layer 32 may be a second silicon nitride layer, the blocking insulating layer 40 may be a SiO₂ layer, and the gate electrode 50 may include n+ poly-Si. Specific compositions and characteristics of the first silicon nitride layer and the second silicon nitride layer may be the same as those described above with reference to FIG. 1.

The first trap layer 31 may have a trap of a shallower level than that of the second trap layer 32, that is, the second trap layer 32 may have a trap of a deeper level than that of the first trap layer 31. In other words, the first trap layer 31 may have a shallower trap level than the second trap layer 32, that is, the second trap layer 32 may have a deeper trap level than the first trap layer 31. FIG. 3 shows a state in which charges (electrons) are trapped in shallow traps of the first trap layer 31, and also shows a state in which charges (electrons) are trapped in deep traps of the second trap layer 32. The first trap layer 31 may have a smaller energy band gap than that of the second trap layer 32.

In a case that the charge trap layer 30 includes the first trap layer 31 and the second trap layer 32, since the charges (electrons) trapped in shallow traps of the first trap layer 31 may escape to the channel member 12 at a relatively high speed when a potentiation voltage (e.g., an erase voltage) is applied, the synaptic operation speed may be improved. In other words, the update speed of the weight of the synapse device may be increased. Meanwhile, since the second trap layer 32 has a deep trap, charge retention characteristics of the charge trap layer 30 may be improved (secured) by the second trap layer 32. During the potentiation operation by applying the potentiation voltage, the charges (electrons) trapped in the deep trap of the second trap layer 32 may move to the shallow trap of the first trap layer 31, and then may exit towards the channel member 12.

FIG. 4 is a diagram showing energy band diagram of a channel region 12, a source 14a/a drain 14b, and a conductor 70a, 70b of a synapse device according to an embodiment of the present invention.

Referring to FIG. 4, the channel region 12 may be a region doped with a P-type dopant, and the source 14a and drain 14b may be regions doped with an N-type dopant. Each of the source 14a and the drain 14b may have a doping level corresponding to the N− level. For example, each of the source 14a and the drain 14b may have a doping concentration of about 1×10¹⁶ to 2×10¹⁸ atoms/cm³. The first and the second conductors 70a and 70b may be formed of or include metal (M). The source 14a may form a Schottky junction together with the first conductor 70a, and the drain 14b may form a Schottky junction together with the second conductor 70b.

When a Schottky junction is formed between the source 14a/drain 14b and the first conductor 70a/second conductor 70b, unlike a typical charge trap-based device, a current section due to a tunneling (TU) mechanism may be generated between a current section due to a thermionic emission (TE) mechanism and a current section due to a drift mechanism, and linearity of weight control (update) of the synapse device may be secured by using the current section due to the tunneling (TU) mechanism.

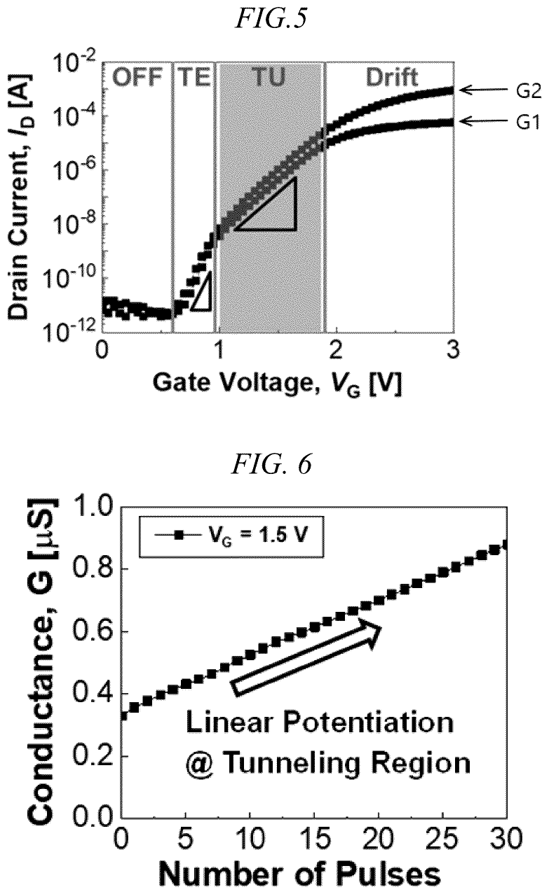

FIG. 5 is a graph showing a change in the drain current I_{D} according to a change in the gate voltage (V_{G}) of a synapse device according to an embodiment of the present disclosure. The result of FIG. 5 may be obtained from the synapse device corresponding to FIG. 4. In FIG. 5, the G1 curve is a curve obtained when the drain voltage V_{D} is 0.05 V, and the G2 curve is a curve obtained when the drain voltage V_{D} is 1 V.

Referring to FIG. 5, in the synapse device according to an embodiment of the present disclosure, it may be confirmed that a current section by the tunneling (TU) mechanism exists between a current section by the thermionic emission (TE) mechanism and a current section by the drift mechanism. Linearity of the weight adjustment (update) characteristics of synapse devices may be secured by using the current section by the tunneling (TU) mechanism.

In the case of a charge trap memory with a general SONOS (silicon/oxide/nitride/oxide/silicon) structure, I_{D}-V_{G} curve may include only a current section by thermionic emission (TE) mechanism and a current section by drift mechanism. However, as in the embodiment of the present disclosure, when a Schottky junction is formed between the source 14a/drain 14b and the first conductor 70a/second conductor 70b, a current section by the tunneling (TU) mechanism may be generated between the current section by the thermionic emission (TE) mechanism and the current section by the drift mechanism. In the current section by the tunneling (TU) mechanism, it is possible to easily secure a linear change characteristic of current. The current section by the tunneling (TU) mechanism may have a relatively smooth slope.

FIG. 6 is a graph showing the results obtained by evaluating the increase characteristic of conductance (G), that is, potentiation characteristic according to the number of voltage pulses applied to a synapse device according to an embodiment of the present disclosure. Such a potentiation characteristic was evaluated in the current section according to the tunneling (TU) mechanism described above (e.g., V_{G}=1.5V in the current section by the tunneling (TU) mechanism in FIG. 5).

Referring to FIG. 6, it may be seen that the weight of the synapse device represented by conductance (G) substantially completely linearly increases in the current section by the tunneling (TU) mechanism having a relatively smooth slope. In addition, when the weight is reduced in this section, the weight may decrease substantially linearly or relatively linearly.

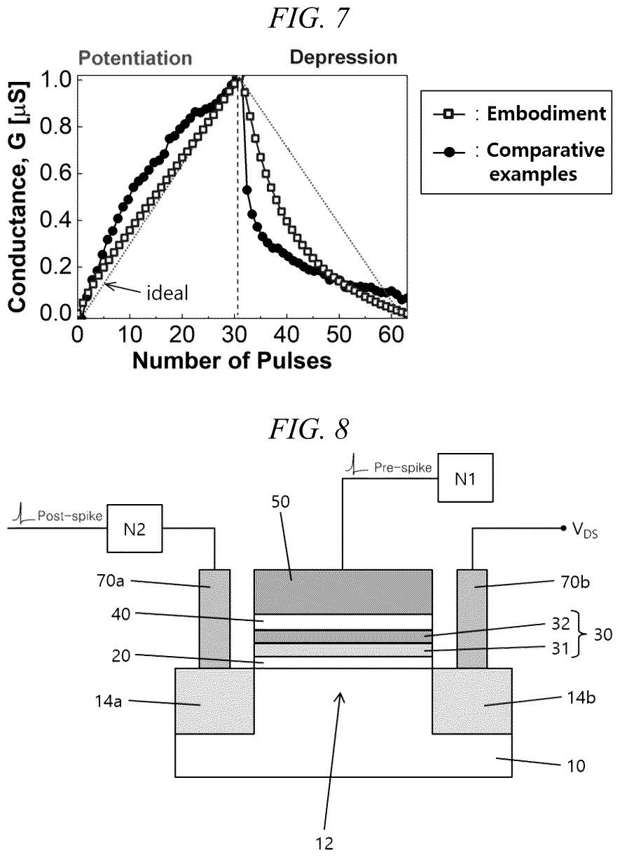

FIG. 7 is a graph showing results of evaluation of potentiation and depression characteristics of a synapse device according to an embodiment of the present disclosure and a synapse device according to a comparative example. The synapse device according to the comparative example has a conventional SONOS structure. A graph indicated by a dotted line in FIG. 7 corresponds to an ideal synaptic weight change.

Referring to FIG. 7, it may be seen that the synapse device according to the embodiment of the present disclosure exhibits characteristics close to the ideal synaptic weight change when compared to the synapse device according to the comparative example. The synapse device according to the embodiment may exhibit characteristics closer to the ideal synaptic weight change than the comparative example in both the potentiation and depression steps. In particular, in the case of a potentiation step, the synapse device according to the embodiment may exhibit excellent linearity that is almost the same level as an ideal synaptic weight change.

When a synapse which is a connection between a pre-neuron and a post-neuron is configured as a circuit, the synapse device according to an embodiment of the present disclosure may be applied. A pre-neuron may input a pre-spike signal into a synapse, the synapse may transmit a synaptic signal to a post-neuron, and a post-neuron may generate a post-spike signal. Similar to a method in which a synapse connects a pre-neuron and a post-neuron, the synapse device may connect a pre-synaptic neuron circuit and a post-synaptic neuron circuit. A circuit diagram of this configuration may be shown as FIG. 8.

FIG. 8 is a cross-sectional view showing a circuit configuration including a synapse device according to an embodiment of the present disclosure.

Referring to FIG. 8, the gate electrode 50 of the synapse device may be connected to a pre-synaptic neuron circuit N1. The source 14a of the synapse device may be connected to a post-synaptic neuron circuit N2 via a first conductor 70a. A pre-spike signal from the pre-synaptic neuron circuit N1 may be applied to the gate electrode 50, and a post-synaptic current may flow through the source 14a to the post-synaptic neuron circuit N2. A post-spike signal may be generated from the post-synaptic neuron circuit N2. Meanwhile, a predetermined voltage V_{DS} may be substantially constantly applied to the drain 14b of the synapse device. The voltage V_{DS} may be a substantially constant voltage. The voltage V_{DS} may be applied to the drain 14b through the second conductor 70b.

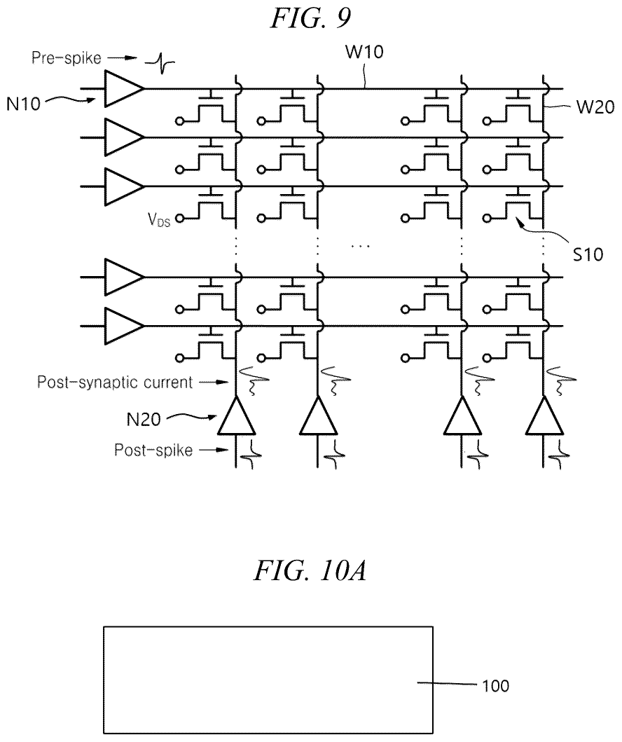

FIG. 9 is a circuit diagram showing a synaptic array device to which a synapse device S10 according to an embodiment of the present disclosure is applied as a unit device.

Referring to FIG. 9, a plurality of synapse devices S10 may be arranged to form a plurality of columns and a plurality of rows. A plurality of first wirings W10 may be arranged, and a plurality of second wirings W20 crossing them may be arranged, and each of the plurality of synapse devices S10 may be provided at the intersection of the first wiring W10 and the second wiring W20. The plurality of first wirings W10 may be connected to the gate electrode of the synapse device S10, and the plurality of second wirings W20 may be connected to the source of the synapse device S10. The first wiring W10 may be connected to a pre-synaptic neuron circuit N10, and the second wiring W20 may be connected to a post-synaptic neuron circuit N20. Meanwhile, a predetermined voltage V_{DS} may be applied to the drain of the synapse device S10.

A pre-spike signal may be applied from the pre-synaptic neuron circuit N10 to the gate electrode of the synapse device S10 through the first wiring W10. A post-synaptic current may flow to the post-synaptic neuron circuit N20 through the source of the synapse device S10. A post-spike signal may be generated from the post-synaptic neuron circuit N20.

According to an embodiment of the present disclosure, it is possible to configure a neuromorphic device and system to which one or more synapse devices according to the above embodiment are applied. The neuromorphic device may include a CMOS peripheral circuit connected to the synapse devices. The CMOS peripheral circuit may include a pre-synaptic neuron circuit and a post-synaptic neuron circuit, etc. The plurality of synapse devices according to an embodiment of the present disclosure, for example, may have an array structure as described in FIG. 9. Since the synapse device according to an embodiment of the present disclosure is compatible with CMOS technology, it is possible to easily implement a neuromorphic device including the synapse device and a CMOS peripheral circuit.

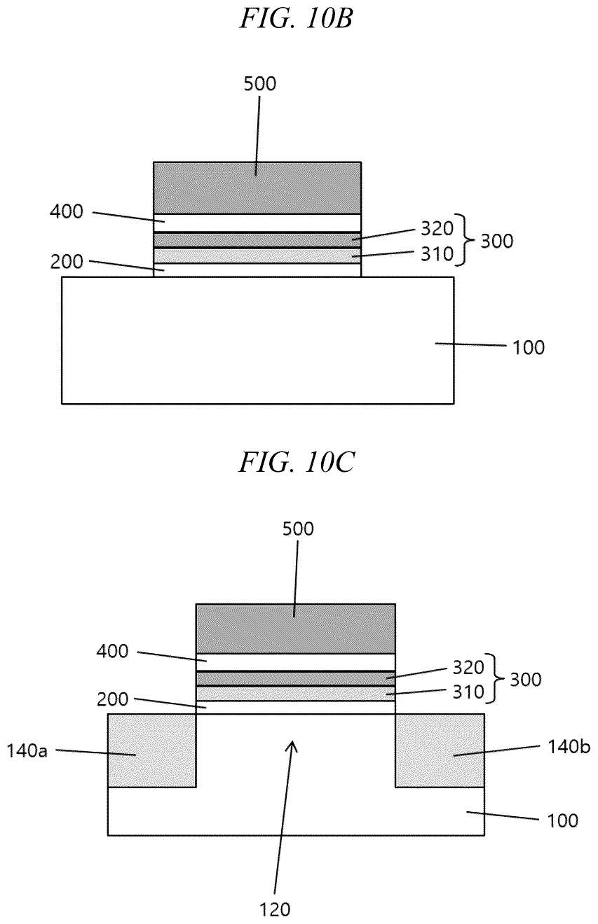

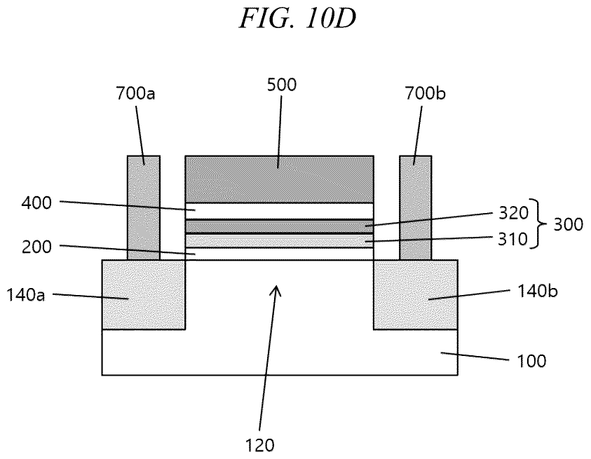

FIG. 10A to FIG. 10D are cross-sectional views showing a manufacturing method of a synapse device according to an embodiment of the present disclosure.

Referring to FIG. 10A, a substrate 100 may be prepared. The substrate 100 may include a predetermined channel member (or channel region) (120 in FIG. 10C). The substrate 100 may be, for example, a semiconductor substrate such as a silicon substrate. The silicon substrate may be a single crystal substrate. At least a portion of the substrate 100 may be doped with a predetermined dopant. The material of the substrate 100 is not limited to silicon and may be changed according to circumstances. For example, the substrate 100 may include any one of various substrates such as a silicon substrate, a germanium substrate, a silicon-germanium substrate, and a silicon carbide substrate.

Referring to FIG. 10B, a stacked structure in which a tunnel insulating layer 200, a charge trap layer 300, a blocking insulating layer 400, and a gate electrode 500 are sequentially stacked may be formed on a substrate 100. It may be said that the stacked structure is disposed on a channel member (or channel region) (120 in FIG. 10C) of the substrate 100. The material composition of each of the tunnel insulating layer 200, the charge trap layer 300, the blocking insulating layer 400, and the gate electrode 500 may be the same as or similar to the material composition of a respective one of the tunnel insulating layer 20, the charge trap layer 30, the blocking insulating layer 40 and the gate electrode 50 described with reference to FIG. 1.

The charge trap layer 300 may be formed to have a multilayer structure including a first trap layer 310 adjacent to the substrate 100 and a second trap layer 320 adjacent to the gate electrode 500. The first trap layer 310 may have a trap of a shallower level than that of the second trap layer 320, that is, the second trap layer 320 may have a trap of a deeper level than that of the first trap layer 310. For example, the first trap layer 310 may be a first silicon nitride layer, and the second trap layer 320 may be a second silicon nitride layer different from the first silicon nitride layer. The first silicon nitride layer may be a Si-rich silicon nitride layer, and the second silicon nitride layer may be a silicon nitride layer having a higher nitrogen (N) content than the first silicon nitride layer. The second silicon nitride layer may include silicon nitride having a stoichiometric composition, or N-rich silicon nitride, or both. The first trap layer 310 may have a smaller energy bandgap than that of the second trap layer 320. The material, the characteristics, and the thickness of each of the first trap layer 310 and the second trap layer 320 may correspond to the material, the characteristics, and the thickness of each of the first trap layer 31 and the second trap layer 32 described with reference to FIG. 1.

Referring to FIG. 10C, a first terminal (e.g., a source) 140a and a second terminal (e.g., a drain) 140b respectively connected to first and second regions (e.g., first and second end portions) of the channel member 120 may be formed. For example, the source 140a and the drain 140b may be formed by doping dopants into regions of the substrate 100 at both sides of the stacked structure including the tunnel insulating layer 200, the charge trap layer 300, the blocking insulating layer 400, and the gate electrode 500. The channel member 120 disposed below the stacked structure may be disposed between the source 140a and the drain 140b to connect them. In other words, the source 140a and the drain 140b may be formed to define the channel member 120 therebetween in the substrate 100.

Referring to FIG. 10D, first and second conductors 700a and 700b respectively bonded to each of the source 140a and the drain 140b may be formed. The first conductor 700a and the second conductor 700b may be made of a predetermined metal or metallic material. As the material of the first conductor 700a and the second conductor 700b, any metal contact material of a general electronic device may be applied.

According to an embodiment, the source 140a and the first conductor 700a may form a Schottky junction, and similarly, the drain 140b and the second conductor 700b also form a Schottky junction. In this regard, each of the source 140a and the drain 140b may have a doping level corresponding to the N− level. For example, each of the source 140a and the drain 140b may have a doping concentration of about 1×10¹⁶ to 2×10¹⁸ atoms/cm³. Under these conditions, the source 140a may form a Schottky junction with the first conductor 700a, and the drain 140b may form a Schottky junction with the second conductor 700b.

Although not shown in FIG. 10D, an interlayer insulating layer may be further formed around the first and second conductors 700a and 700b. The interlayer insulating layer may be formed on the substrate 100 to cover the source 140a and the drain 140b. First and second contact holes may be formed in the interlayer insulating layer, and the first and the second conductors 700a and 700b may be formed in the first and second contact holes, respectively. The first and second conductors 700a and 700b may be a kind of conductive plug.

The synapse device manufactured by the method of FIGS. 10A to 10D may correspond to the synapse device according to the embodiments described with reference to FIGS. 1 to 7. Therefore, the contents described with reference to FIGS. 1 to 7 may also be applied to the synapse device of FIG. 10D.

Additionally, although FIGS. 1 and 10A to 10D show and describe the case where the synapse device has a planar-type transistor structure, the specific structure of the synapse device may be variously changed. For example, the synapse device may have a fin field effect transistor (FinFET) structure, a gate-all-around (GAA) transistor structure, and the like. In addition, the specific structure of the synapse device may be variously changed.

According to the embodiments of the present disclosure described above, it is possible to implement a synapse device capable of increasing the speed of an operation related to synaptic weight update. In addition, according to embodiments of the present disclosure, it is possible to implement a synapse device capable of securing or improving linearity when adjusting synaptic weights. In addition, according to embodiments of the present disclosure, it is possible to implement a synapse device having excellent process compatibility with CMOS technology. For example, a synapse device according to embodiments may be substantially completely compatible with conventional CMOS technology. Therefore, the synapse device according to these embodiments may be used as an artificial synapse which may replace a biological synapse, and may be usefully used for a neuromorphic device (neuromorphic system) and a neural network.

In this specification, the preferred embodiments of the present disclosure have been disclosed, and although specific terms have been used, they are only used in a general sense to easily explain the technological content of the present disclosure and to help understanding embodiments of the present disclosure, and they are not used to limit the scope of embodiments of the present disclosure. It is obvious to those having ordinary skill in the related art to which the present disclosure belong that other modifications based on the technological idea of the present disclosure may be implemented in addition to the embodiments disclosed herein. It will be understood to those having ordinary skill in the related art that in connection with a synapse device, a manufacturing method thereof, and a neuromorphic device including the synapse device according to the embodiments described with reference to FIGS. 1 to 10D, various substitutions, changes, and modifications may be made without departing from the technological spirit of the present disclosure. Therefore, the scope of the invention should not be determined by the described embodiments, but should be determined by the technological concepts described in the claims.

### EXPLANATION OF SYMBOLS

* Explanation of symbols for the main parts of the drawing *

| | |
|---|---|
| 10: substrate | 12: channel member |
| 14a: source | 14b: drain |
| 20: tunnel insulating layer | 30: charge trap layer |
| 31: first trap layer | 32: second trap layer |
| 40: blocking insulating layer | 50: gate electrode |
| 70a: first conductor | 70b: second conductor |
| N1: pre-synaptic neuron circuit | N2: post-synaptic neuron circuit |
| N10: pre-synaptic neuron circuit | N20: post-synaptic neuron circuit |
| S10: synapse device | W10: first wiring |
| W20: second wiring | |

What is claimed is:

1. A synapse device comprising:
a channel member;
a tunnel insulating layer disposed on the channel member;
a charge trap layer disposed on the tunnel insulating layer;
a blocking insulating layer disposed on the charge trap layer;
a gate electrode disposed on the blocking insulating layer;
a first terminal and a second terminal respectively connected to first and second regions of the channel member; and
first and second conductors respectively bonded to the first and second terminals,
wherein the charge trap layer has a multilayer structure including a first trap layer disposed adjacent to the channel member and a second trap layer disposed adjacent to the gate electrode, and
wherein the first trap layer has a trap of a shallower level than that of the second trap layer.

2. The synapse device of claim 1, wherein the first trap layer is a first silicon nitride layer, and the second trap layer is a second silicon nitride layer different from the first silicon nitride layer.

3. The synapse device of claim 2, wherein the first silicon nitride layer is a silicon (Si)-rich silicon nitride layer, and the second silicon nitride layer is a silicon nitride layer having a higher nitrogen (N) content than the first silicon nitride layer.

4. The synapse device of claim 3, wherein the second silicon nitride layer includes silicon nitride having a stoichiometric composition, or N-rich silicon nitride, or both.

5. The synapse device of claim 3, wherein the first silicon nitride layer has a silicon (Si) content in a range from about 43 at % to about 86 at %.

6. The synapse device of claim 3, wherein the second silicon nitride layer has a silicon (Si) content in a range from about 14 at % to about 43 at %.

7. The synapse device of claim 1, wherein the first trap layer has a smaller energy bandgap than that of the second trap layer.

8. The synapse device of claim 1, wherein the first terminal is a source and the second terminal is a drain, and
wherein the source and the first conductor form a Schottky junction, and the drain and the second conductor form a Schottky junction.

9. The synapse device of claim 8, wherein each of the source and the drain has a doping concentration of 1×10¹⁶ to 2×10¹⁸ atoms/cm³.

10. A neuromorphic device comprising the synapse device according to claim 1.

11. The neuromorphic device of claim 10, further comprising a CMOS peripheral circuit connected to the synapse device.

12. A method for manufacturing a synapse device, the method comprising:
forming a stacked structure by sequentially stacking a tunnel insulating layer, a charge trap layer, a blocking insulating layer, and a gate electrode on a channel member;
forming a first terminal and a second terminal respectively connected to first and second regions of the channel member; and
forming first and second conductors respectively bonded to the first and second terminals,
wherein the charge trap layer is formed to have a multilayer structure including a first trap layer disposed adjacent to the channel member and a second trap layer disposed adjacent to the gate electrode, and
wherein the first trap layer has a trap of a shallower level than that of the second trap layer.

13. The method of claim 12, wherein the first trap layer is a first silicon nitride layer, and the second trap layer is a second silicon nitride layer different from the first silicon nitride layer.

14. The method of claim 13, wherein the first silicon nitride layer is a silicon (Si)-rich silicon nitride layer, and the second silicon nitride layer is a silicon nitride layer having a higher nitrogen (N) content than the first silicon nitride layer.

15. The method of claim 14, wherein the second silicon nitride layer includes silicon nitride having a stoichiometric composition, or N-rich silicon nitride, or both.

16. The method of claim 14, wherein the first silicon nitride layer has a silicon (Si) content in a range from about 43 at % to about 86 at %.

17. The synapse device of claim 14, wherein the second silicon nitride layer has a silicon (Si) content in a range from about 14 at % to about 43 at %.

18. The method of claim 12, wherein the first trap layer has a smaller energy bandgap than that of the second trap layer.

19. The method of claim 12, wherein the first terminal is a source and the second terminal is a drain, and
wherein the source and the first conductor form a Schottky junction, and the drain and the second conductor form a Schottky junction.

20. The method of claim 19, wherein each of the source and the drain has a doping concentration of 1×10¹⁶ to 2×10¹⁸ atoms/cm³.
